(19) United States
(12) Patent Application Publication
(10) Pub. No.: US 2012/0290239 A1
(43) Pub. Date: Nov. 15, 2012

(54) THIN METAL FILM MEASUREMENT METHOD

(75) Inventors: Yi-Sha Ku, Hsinchu City (TW); Po-Yi Chang, Taichung City (TW); Yi-Chang Chen, Miaoli City (TW); Hsiu-lan Pang, Baoshan Township (TW)

(73) Assignee: INDUSTRIAL TECHNOLOGY RESEARCH INSTITUTE, HSINCHU (TW)

(21) Appl. No.: 13/215,641

(22) Filed: Aug. 23, 2011

(30) Foreign Application Priority Data
May 11, 2011 (TW) 100116550

(51) Int. Cl. G01R 27/26

(52) U.S. Cl. 702/65

(57) ABSTRACT

A thin metal film measurement method is disclosed. The method includes the following steps. A respective capacitance is measured before and after a thin metal film is formed. The thickness of the thin metal film is calculated according to the variation of the capacitance. In an embodiment, the capacitance is measured respectively by a capacitance measuring module before and after the thin metal film is formed so as to calculate the thickness of the thin metal film. In another embodiment, a pair of capacitance measuring modules opposite at up and down sides is applied to measure the capacitance before and after the thin metal film is formed so as to calculate the thickness of the thin metal film.

This application claims the benefit of Taiwan application Serial No. 100116550, filed May 11, 2011, the subject matter of which is incorporated herein by reference.

### BACKGROUND

### Technical Field

The disclosure relates in general to a thin metal film measurement method, and more particularly to a non-destructive thin metal film measurement method to get the information of the thickness and surface morphology.

Along with the advance in semiconductor process technology, metal coating process combined with etching or grinding process is widely used in the manufacturing of integrated circuit, and has become a key technology in the semiconductor process technology. However, the thin metal film is impermeable to the light, and it is very difficult to perform non-contact, non-destructive measurement on the thin metal film. Conventionally, destructive and contact four point probe measurement method is applied to measure the thickness of the film.

In recent years, non-contact film thickness measurement method has attracted more and more attention. There are a number of generally known technologies including: (1) Applying a specific amount of heat to a specific part of a thin metal film and then estimating the thickness of the thin metal film according to the temperature change on the thin metal film. (2) Applying a pulse energy to a thin metal film, and then estimating the thickness of the thin metal film according to the amplitude and frequency of the generated sound wave. (3) Applying a magnetic field of Helmholtz coil to a thin metal film, and then estimating the thickness of the thin metal film according to the loss of the eddy current. However, the above measurement methods require a complete theoretic model and comparison database to accurately estimate the thickness of the thin metal film.

### SUMMARY

The disclosure is directed to a thin metal film measurement method. The thickness of the thin metal film is calculated according to the capacitance induced between the thin metal film and the capacitance measuring module and the thickness of the thin metal film, which is measured in a non-contact and non-destructive manner, and the capacitance variation before and after the coating process. Besides, the information of the thickness on different measuring points can be recorded so as to establish a systemized data model for the user to identify the surface morphology and the warpage of the thin metal film.

According to an aspect of the present disclosure, a thin metal film measurement method is disclosed. The method includes the following steps. A respective capacitance is measured before and after a thin metal film is formed. The thickness of the thin metal film is calculated according to the variation of the capacitance.

According to an alternative aspect of the present disclosure, the thin metal film measurement method further includes recording the information of the thickness of the thin metal film at a plurality of measuring points so as to establish a data model related to the surface morphology of the thin metal film. Besides, the thin metal film measurement method further includes calculating the warpage of the thin metal film according to the surface morphology of the thin metal film.

The above and other aspects of the disclosure will become better understood with regard to the following detailed description of the non-limiting embodiment(s). The following description is made with reference to the accompanying drawings.

### BRIEF DESCRIPTION OF THE DRAWINGS

FIG. 1 shows a flowchart of a thin metal film measurement method according to an embodiment;

FIGS. 2A and 2B show a capacitance measuring module measuring the capacitance according to a first embodiment;

FIGS. 3A and 3B show a capacitance measuring module measuring the capacitance according to a second embodiment;

FIG. 4 shows a thin metal film measurement method according to an embodiment; and

FIGS. 5A and 5B respectively show a thickness distribution diagram and a surface morphology diagram of a thin metal film according to an embodiment.

### DETAILED DESCRIPTION

According to the thin metal film measurement method of the present embodiment, the thickness of the thin metal film is calculated by measuring a capacitance induced between the thin metal film and a capacitance measuring module and a capacitance variation before and after the coating process. The induced current flowing between a capacitor plate and the to-be-detected object is measured according to the principles of operation of the capacitance measuring module, and the larger the induced current, the larger the capacitance. The capacitance calculation formula is expressed as:

$$\begin{matrix}C = \frac{Q}{V} = \frac{I t}{V} & ( 1 ) \\ C = ɛ \frac{A}{d} & ( 2 )\end{matrix}$$

Wherein ∈ denotes a dielectric constant; A denotes the area of a capacitor plate; d denotes the distance between the capacitor plate and the to-be-detected object; I denotes the current flowing between the capacitor plate and the to-be-detected object; V denotes a potential energy applied by the capacitor plate; Q denotes an accumulated quantity of electric charge. The quantity of electric charge Q is equal to the current I multiplied by a power-on time t. The capacitance C is the quotient of the quantity of electric charge Q divided by the potential energy V as indicated in formula (1). Then, the distance d between the capacitor plate and the to-be-detected object is calculated according to the known capacitance C as indicated in formula (2).

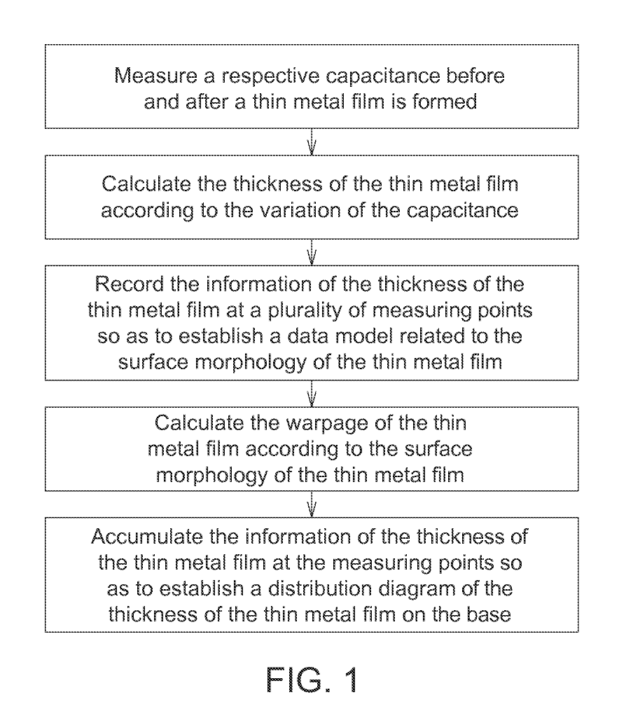

As indicated in the capacitance calculation formula, as the distance between the capacitor plate and the to-be-detected object varies, the capacitance varies as well. Thus, in the present embodiment, the thickness of the thin metal film is calculated according to the capacitance respectively measured before and after the thin metal film is formed and according to the variation of the capacitance. Referring to FIG. 1, a flowchart of a thin metal film measurement method according to an embodiment is shown. The method includes the following steps:

(1) Measuring a respective capacitance before and after a thin metal film is formed;

(2) Calculating the thickness of the thin metal film according to the variation of the capacitance;

(3) Recording the information of the thickness of the thin metal film at a plurality of measuring points so as to establish a data model related to the surface morphology of the thin metal film;

(4) Calculating the warpage of the thin metal film according to the data model of surface morphology of the thin metal film;

(5) Accumulating the information of the thickness of the thin metal film at the measuring points so as to establish a distribution diagram of the thickness of the thin metal film on the base.

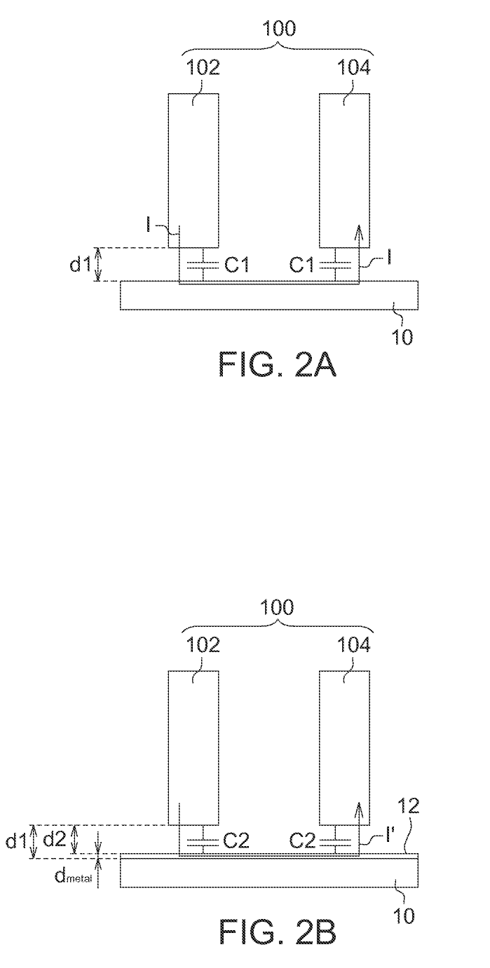

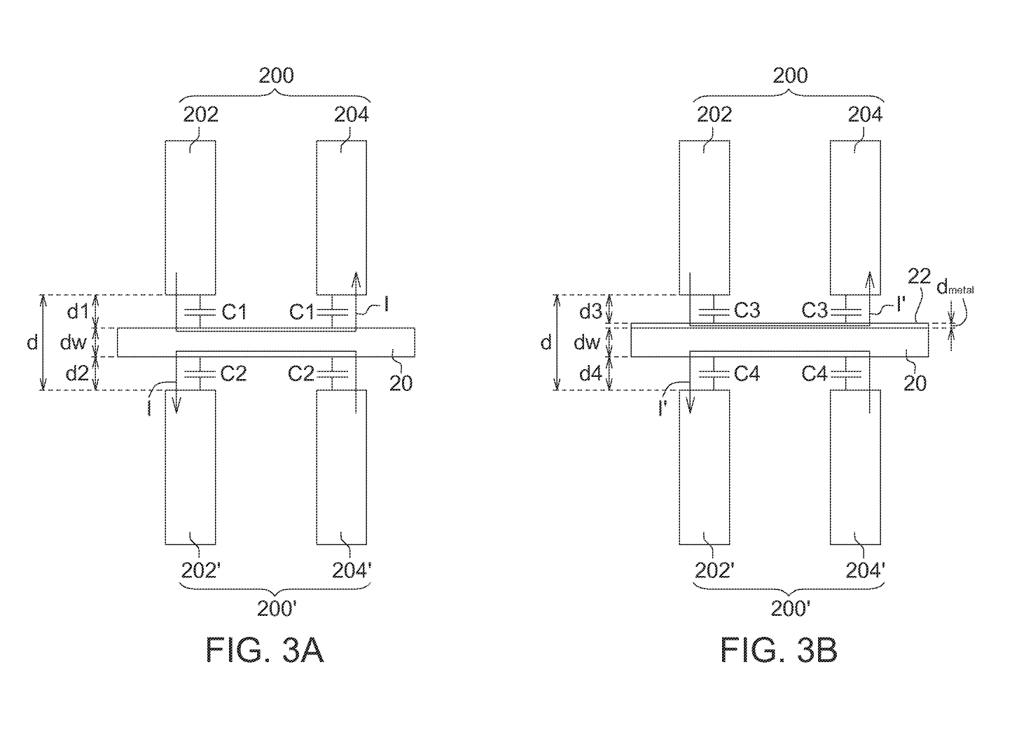

A number of embodiments are disclosed below. However, the embodiments are for detailed descriptions, not for limiting the scope of protection of the disclosure. Referring to FIGS. 2A and 2B. In the first embodiment, a dual-channel capacitance measuring module 100 is applied to measure a respective capacitance before and after the thin metal film 12 is formed so as to calculate the thickness dmetal of the thin metal film 12. Referring to FIGS. 3A and 3B. In the second embodiment, a pair of dual-channel capacitance measuring modules 200 and 200′ opposite at up and down sides is applied to measure a respective capacitance before and after the thin metal film 22 is formed so as to calculate the thickness dmetal of the thin metal film 22.

### First Embodiment

The processes of the thin metal film measurement method of the first embodiment are disclosed below. The steps of measuring the capacitance and calculating the thickness of the thin metal film 12 by the capacitance measuring module 100 are disclosed below with accompanying drawings FIGS. 2A and 2B.

(1) Applying a voltage to a capacitance measuring module 100, so that a first capacitance C1 is induced between the capacitance measuring module 100 and the base 10;

(2) Converting a first interval d1 corresponding to the first capacitance C1 according to the capacitance calculation formula;

(3) Forming a thin metal film 12 on the base 10;

(4) Applying the same magnitude of voltage to the capacitance measuring module 100, so that a second capacitance C2 is induced between the capacitance measuring module 100 and the thin metal film 12;

(5) Converting a second interval d2 corresponding to the second capacitance C2 according to the capacitance calculation formula; and

(6) Calculating the thickness dmetal of the thin metal film 12.

Referring to FIG. 2A, the capacitance measuring module 100 includes a first capacitor plate 102 and a second capacitor plate 104. The first capacitor plate 102 applies a forward (or backward) voltage for transmitting an induced current Ito the base 10. The second capacitor plate 104 applies a voltage inverse to the first capacitor plate 102 for receiving the induced current I transmitted from the base 10. According to the present embodiment, a synchronic forward and backward voltages are applied to force the induced current Ito exit the first capacitor plate 102 and then enter the second capacitor plate 104 through the surface of the base 10, the first capacitance C1 is measured, and the first interval d1 corresponding to the first capacitance C1 is converted. As indicated in formula (2), the first capacitance C1 is inversely proportional to the first interval d1.

Referring to FIG. 2B. After the thin metal film 12 is formed on the base 10, then the induced current I′ no more flows through the surface of the base 10 but enters the second capacitor plate 104 through the surface of thin metal film 12 instead. Meanwhile, the first capacitance C1 varies due to the change in distance, so that a second capacitance C2 is induced between the capacitance measuring module 100 and the thin metal film 12. As indicated in formula (2), the second capacitance C2 is inversely proportional to the second interval d2. Thus, the thickness of the thin metal film 12 is the difference obtained by deducting the second interval d2 from the first interval d1, that is, the thickness dmetal=d1−d2.

### Second Embodiment

The processes of the thin metal film measurement method of the second embodiment are disclosed below. The steps of measuring the capacitance and calculating the thickness of the thin metal film 22 by a pair of capacitance measuring modules 200 and 200′ is disclosed below with accompanying drawings FIGS. 3A and 3B.

(1) Placing a base 20 between a pair of capacitance measuring modules 200 and 200′, wherein a fixed interval d is formed between the pair of capacitance measuring modules 200 and 200′;

(2) Applying a pair of voltages to the pair of capacitance measuring modules 200 and 200′, so that a first capacitance C1 and a second capacitance C2 are respectively induced between the pair of capacitance measuring modules 200 and 200′ and the base 20;

(3) Converting a first interval d1 and a second interval d2 respectively corresponding to the first capacitance C1 and the second capacitance C2 according to the capacitance calculation formula;

(4) Calculating the thickness dw of the base 20 according to the first interval d1 and the second interval d2;

(5) Forming a thin metal film 22 on the base 20;

(6) Applying a pair of voltages having the same magnitude to the pair of capacitance measuring modules 200 and 200′, so that a third capacitance C3 and a fourth capacitance C4 are respectively induced between the pair of capacitance measuring modules 200 and 200′ and the thin metal film 22 and the base 20;

(7) Converting a third interval d3 and a fourth interval d4 respectively corresponding to the third capacitance C3 and the fourth capacitance C4 according to the capacitance calculation formula; and

(8) Calculating the thickness dmetal of the thin metal film 22.

Referring to FIG. 3A. The pair of capacitance measuring modules 200 and 200′ includes two first capacitor plates 202 and 202′ opposite at up and down sides and two second capacitor plates 204 and 204′ opposite at up and down sides. Each of the first capacitor plates 202 and 202′ applies a forward (or backward) voltage for transmitting an induced current I to the base 20. Each of the second capacitor plates 204 and 204′ applies a voltage inverse to the first capacitor plates 202 and 202′ for receiving the induced current I transmitted from the base 20. According to the present embodiment, a synchronic forward and backward voltages are applied to force the induced current I to exit each of the first capacitor plates 202 and 202′ and then enter each of the second capacitor plates 204 and 204′ through the surface of the base 20, a first capacitance C1 and a second capacitance C2 are measured, and a first interval d1 and a second interval d2 corresponding to the first capacitance C1 and the second capacitance C2 are converted. As indicated in FIG. 3A, the thickness of the base 20 is the difference obtained by deducting the first interval d1 and the second interval d2 from a fixed interval d, that is, dw=d−d1−d2.

Referring to FIG. 3B. After the thin metal film 22 is formed on the base 20, the induced current I′ no more flows through the surface of the base 20 but enters the second capacitor plates 204 and 204′ through the surface of thin metal film 22 instead. Meanwhile, the first capacitance C1 varies due to the change in distance, so that a third capacitance C3 and a fourth capacitance C4 are respectively induced between the pair of capacitance measuring modules 200 and 200′ and the thin metal film 22 and the base 20. As indicated in formula (2), the third capacitance C3 is inversely proportional to the third interval d3, and the fourth capacitance C4 is inversely proportional to the third interval d3. Thus, the thickness of the thin metal film 22 is the difference obtained by deducting the base thickness dw, the third interval d3 and the fourth interval d4 from the fixed interval d, that is, the thickness dmetal=d−dw−d3−d4. Unlike the first embodiment, the relative position of the base 20 with respect to the capacitance measuring modules 200 and 200′ may vary before and after the coating process. If the capacitance measuring module 200 and 200′ are designed to be opposite at up and down sides and the interval d is a fixed value, then the thickness of the thin metal film 22 can be calculated despite the relative position of the base 20 with respect to the capacitance measuring modules 200 and 200′ may vary.

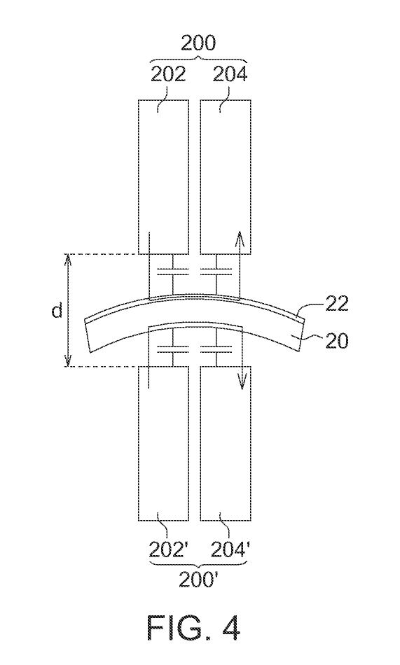

Besides, the warpage of the base 20 before and after the coating process may vary due to lattice mismatch between the metal film and the silicon wafer material or due to difference in the coefficient of temperature expansion (CTE). Referring to FIG. 4, a thin metal film measurement method according to an embodiment is shown. When the base 20 warps and the shape of the base 20 changes, the thickness of the thin metal film 22 at different measuring points still can be calculated as in the second embodiment as long as the capacitance measuring module 200 and 200′ are designed opposite at up and down sides and the interval d is a fixed value.

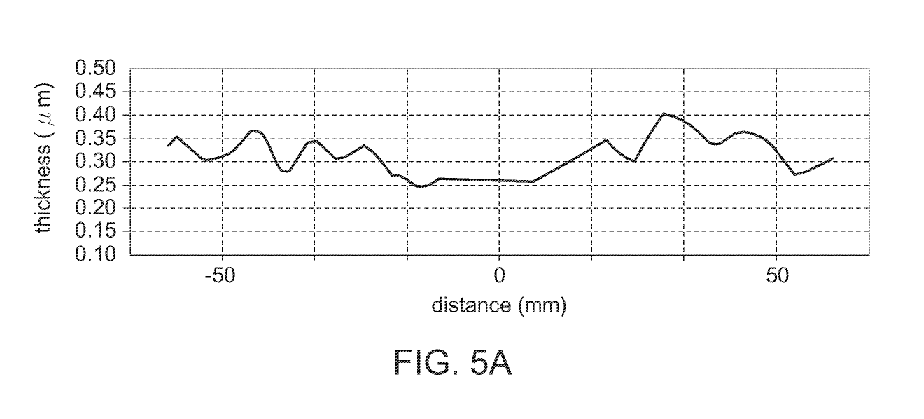

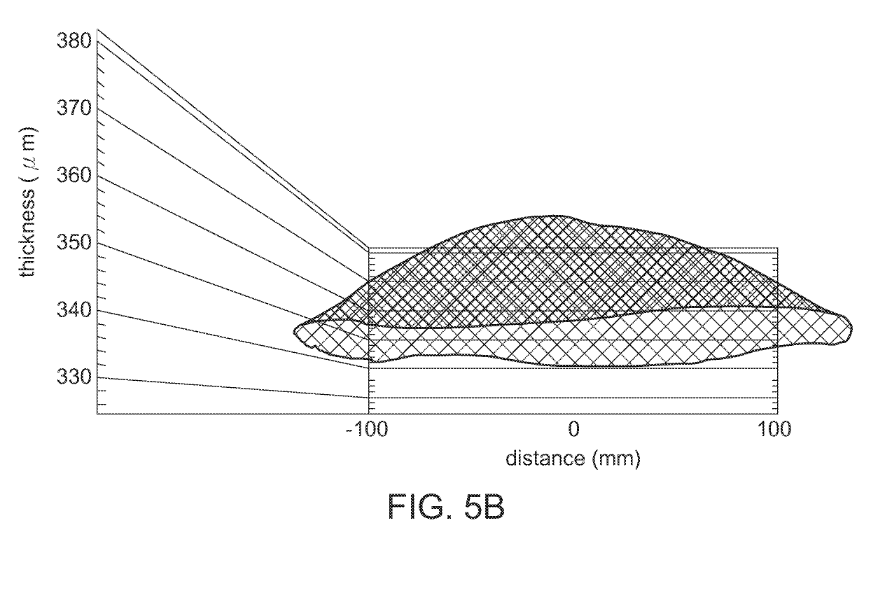

According to the present embodiment, the information of the thickness of a thin metal film at a certain number of measuring points are respectively recorded, and a data model related to the surface morphology of the thin metal film are systematically established, so that a distribution diagram of the thickness of the thin metal film on the base is presented in a 3D diagram or chart for the user to obtain knowledge of the surface morphology and the warpage of the thin metal film. Referring to FIGS. 5A and 5B, a thickness distribution diagram and a surface morphology diagram of a thin metal film according to an embodiment are respectively shown. The information of the thickness of the thin metal film at respective measuring points can be obtained from the thickness distribution diagram, wherein the information of the thickness of the thin metal film includes minimum thickness, maximum thickness, central thickness, average thickness, total thickness variation (TTV). Besides, the warpage of the thin metal film with different coating thickness can be obtained from the comparison between the surface morphology diagrams before and after the coating process.

According to the thin metal film measurement method disclosed in the embodiments, the thickness of the thin metal film is calculated according to the capacitance induced between the thin metal film and the capacitance measuring module, which is measured in a non-contact and non-destructive manner, and the capacitance variation before and after the coating process. Thus, the thickness of the thin metal film can be measured more quickly and precisely. Besides, the information of the thickness on different measuring points can be recorded so as to establish a systemized data model for the user to identify the surface morphology and the warpage of the thin metal film more conveniently.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A thin metal film measurement method, comprising:
measuring a respective capacitance before and after the thin metal film is formed; and
calculating a thickness of the thin metal film according to the variation of the capacitance.

2. The thin metal film measurement method according to claim 1, wherein the step of measuring the capacitance comprises:
applying a voltage to a capacitance measuring module before the thin metal film is formed on a base, so that a first capacitance is induced between the capacitance measuring module and the base;
calculating a first interval corresponding to the first capacitance;
applying the voltage to the capacitance measuring module after the thin metal film is formed on the base, so that a second capacitance is induced between the capacitance measuring module and the thin metal film; and
calculating a second interval corresponding to the second capacitance, wherein the thickness of the thin metal film is the difference between the first interval and the second interval.

3. The thin metal film measurement method according to claim 2, wherein the capacitance measuring module comprises a first capacitor plate and a second capacitor plate, the first capacitor plate applies a first voltage for transmitting an induced current, and the second capacitor plate applies a second voltage inverse to the first voltage of the first capacitor plate for receiving the induced current.

4. The thin metal film measurement method according to claim 3, wherein the induced current is transmitted through the base before the thin metal film is formed on the base, and the induced current is transmitted through a surface of the thin metal film after the thin metal film is formed on the base.

5. The thin metal film measurement method according to claim 1, wherein the step of measuring the capacitance comprises:
placing a base between a pair of capacitance measuring modules, wherein a fixed interval is formed between the pair of capacitance measuring modules;
applying a pair of voltages to the pair of capacitance measuring modules before the thin metal film is formed on the base, so that a first capacitance and a second capacitance are respectively induced between the pair of capacitance measuring modules and the base;
converting a first interval and a second interval corresponding to the first capacitance and the second capacitance respectively according to a capacitance calculation formula;
calculating a thickness of the base according to the first interval and the second interval;
applying the pair of voltages to the pair of capacitance measuring modules after the thin metal film is formed on the base, so that a third capacitance and a fourth capacitance are respectively induced between the pair of capacitance measuring modules and the thin metal film and the base; and
converting a third interval and a fourth interval corresponding to the third capacitance and the fourth capacitance respectively according to the capacitance calculation formula, wherein the thickness of the thin metal film is a difference obtained by deducting the thickness of the base, the third interval and the fourth interval from the fixed interval.

6. The thin metal film measurement method according to claim 5, wherein the pair of capacitance measuring modules comprises two first capacitor plates opposite at up and down sides and two second capacitor plates opposite at up and down sides, each first capacitor plate applies a forward voltage for transmitting an induced current, and each second capacitor plate applies a backward voltage for receiving the induced current.

7. The thin metal film measurement method according to claim 6, wherein the induced current is transmitted through a surface of the base before the thin metal film is formed on the base, and the induced current is transmitted through a surface of the thin metal film after the thin metal film is formed on the base.

8. The thin metal film measurement method according to claim 1, further comprising:
recording information of the thickness of the thin metal film at a plurality of measuring points so as to establish a data model related to a surface morphology of the thin metal film.

9. The thin metal film measurement method according to claim 8, further comprising:
calculating warpage of the thin metal film according to the data model and the surface morphology of the thin metal film.

10. The thin metal film measurement method according to claim 9, further comprising: accumulating the information of the thickness of the thin metal film at the measuring points so as to establish a distribution diagram of the thickness of the thin metal film on the base.

11. The thin metal film measurement method according to claim 10, wherein the information of the thickness of the thin metal film at the measuring points comprises minimum thickness, maximum thickness, central thickness, average thickness, and total thickness variation (TTV).

12. The thin metal film measurement method according to claim 3, comprising:
calculating the capacitance or a capacitor plate interval according to a capacitance calculation formula, wherein the capacitance calculation formula comprises:
calculating a quotient of the quantity of electric charge divided by a potential energy to obtain a capacitance;
dividing the capacitance by a dielectric constant multiplied by an area of the first capacitor plate to calculate the first interval distance;
dividing the capacitance by the dielectric constant multiplied by an area of the second capacitor plate to calculate the second interval distance; and
the capacitance is inversely proportional to the first interval or the second interval.
